(19) United States
(12) Patent Application Publication
(10) Pub. No.: US 2025/0279762 A1
(43) Pub. Date: Sep. 4, 2025

(54) ELASTIC WAVE DEVICE AND COMMUNICATION APPARATUS

(71) Applicant: KYOCERA CORPORATION, Kyoto-shi, Kyoto (JP)

(72) Inventor: Naofumi KASAMATSU, Kyoto-shi (JP)

(73) Assignee: KYOCERA CORPORATION, Kyoto-shi, Kyoto (JP)

(21) Appl. No.: 18/857,540

(22) PCT Filed: Apr. 18, 2023
(86) PCT No.: PCT/JP2023/015446

§ 371 Date: Oct. 17, 2024

(30) Foreign Application Priority Data
Apr. 22, 2022 (JP) 2022-070800

(51) Int. Cl. H03H 9/13; H03H 9/17

(52) U.S. Cl. CPC H03H 9/13; H03H 9/17

(57) ABSTRACT

An elastic wave device reduces spurious signals and mitigates stress in a piezoelectric-body layer. The device includes: a support substrate; a piezoelectric-body layer located on the support substrate; and at least one IDT electrode located on the piezoelectric-body layer. When a wavelength λ of an elastic wave excited by the IDT electrode is defined as a length twice an electrode finger pitch of the IDT electrode, a maximum thickness of the piezoelectric-body layer is not more than λ. The IDT electrode excites a plate or bulk wave as the elastic wave. The piezoelectric-body layer includes a first region having a first thickness, a second region having a smaller thickness than the first thickness, and an inclined region located between the first and second regions, and having a thickness that increases from a side at which the second region is provided to a side at which the first region is provided.

### TECHNICAL FIELD

One aspect of the present disclosure relates to an elastic wave device.

### BACKGROUND OF INVENTION

The following Patent Document 1 discloses a configuration example of an elastic wave device.

### CITATION LIST

### Patent Literature Patent Document 1: JP 2016-72808 A

### SUMMARY

An elastic wave device according to one aspect of the present disclosure includes a support substrate, a piezoelectric-body layer located on the support substrate, and at least one IDT electrode located on the piezoelectric-body layer. When a wavelength λ of an elastic wave excited by the IDT electrode is defined as a length twice an electrode finger pitch of the IDT electrode, a maximum thickness of the piezoelectric-body layer is not more than λ. The IDT electrode excites a plate wave or a bulk wave as the elastic wave, and the piezoelectric-body layer includes a first region having a first thickness, a second region having a second thickness smaller than the first thickness, and an inclined region located between the first region and the second region, and having a thickness that increases from a side at which the second region is provided to a side at which the first region is provided.

### BRIEF DESCRIPTION OF THE DRAWINGS

FIG. 1 is a diagram illustrating a configuration example of an elastic wave device according to a first embodiment.

FIG. 2 is a diagram illustrating another configuration example of an elastic wave device according to the first embodiment.

FIG. 3 is a diagram illustrating another configuration example of an elastic wave device according to the first embodiment.

FIG. 4 is a diagram illustrating a configuration example of an elastic wave device as a comparative example.

FIG. 5 is a diagram illustrating an example of a correspondence between an electrode finger pitch (p) and T (thickness of a piezoelectric-body layer) obtained by the inventor.

FIG. 6 is a diagram illustrating an example of a correspondence between T, frequency, and phase obtained by the inventor.

FIG. 7 is a diagram illustrating an overview of a simulation model SIM1 of the elastic wave device.

FIG. 8 is a diagram illustrating an example of phase characteristics of SIM1 and a comparative model.

FIG. 9 is a diagram schematically illustrating an AFM image of a piezoelectric-body layer actually manufactured.

FIG. 10 is a diagram illustrating an overview of a simulation model SIM2 of a piezoelectric-body layer.

FIG. 11 is a diagram illustrating an overview of a simulation model SIM3 of a piezoelectric-body layer.

FIG. 12 is a diagram illustrating yet another configuration example of an elastic wave device according to the first embodiment.

FIG. 13 is a diagram illustrating yet another configuration example of an elastic wave device according to the first embodiment.

FIG. 14 is a diagram illustrating a configuration example of an elastic wave device according to a second embodiment.

FIG. 15 is a diagram illustrating a schematic configuration of a communication apparatus according to a third embodiment.

### DESCRIPTION OF EMBODIMENTS

### First Embodiment

Each elastic wave device according to a first embodiment will be described below. For convenience of description, a member having the same function as that of a member described in the first embodiment will be denoted by the same reference sign in each of subsequent embodiments, and a description thereof will not be repeated. For the sake of brevity, descriptions of known technical matters will be omitted as appropriate. Each component, material, and numerical value described herein are examples only, unless otherwise inconsistent. Thus, for example, unless otherwise inconsistent, the positional relationship of each component is not limited to the examples in each drawing. In addition, the illustration of each component is not necessarily to scale.

### Configuration Example of Elastic Wave Device 100

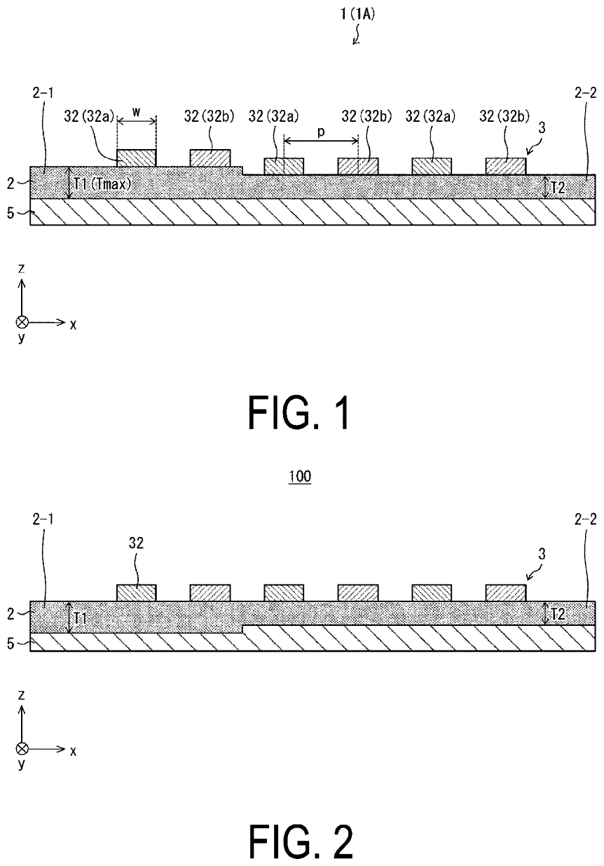

FIG. 1 is a diagram illustrating a configuration example of an elastic wave device 100 according to the first embodiment. FIG. 1 schematically illustrates a laminated structure of the elastic wave device 100. In the following description, a rectangular coordinate system (xyz coordinate system) illustrated in FIG. 1 is introduced for convenience. In the example of the first embodiment, the x-direction is a propagation direction of an elastic wave propagating in a piezoelectric-body layer 2 of the elastic wave device 100. In contrast, a y-direction is an example of a direction intersecting the x-direction. The z-direction is a thickness direction of each member of the elastic wave device 100. In the following, the positive z-direction will be described as the upward direction. Thus, the negative direction in the z-direction is the downward direction.

The elastic wave device 100 may include at least one resonator 1. The elastic wave device 100 may include (i) a support substrate 5, (ii) the piezoelectric-body layer 2 located on the support substrate 5, and (iii) at least one interdigital transducer (IDT) electrode 3 located on the piezoelectric-body layer 2. An IDT electrode 3 is also referred to as an excitation electrode. Each of at least one resonator 1 may share the support substrate 5 and the piezoelectric-body layer 2. On the other hand, each of the at least one resonator 1 may include individual IDT electrodes 3.

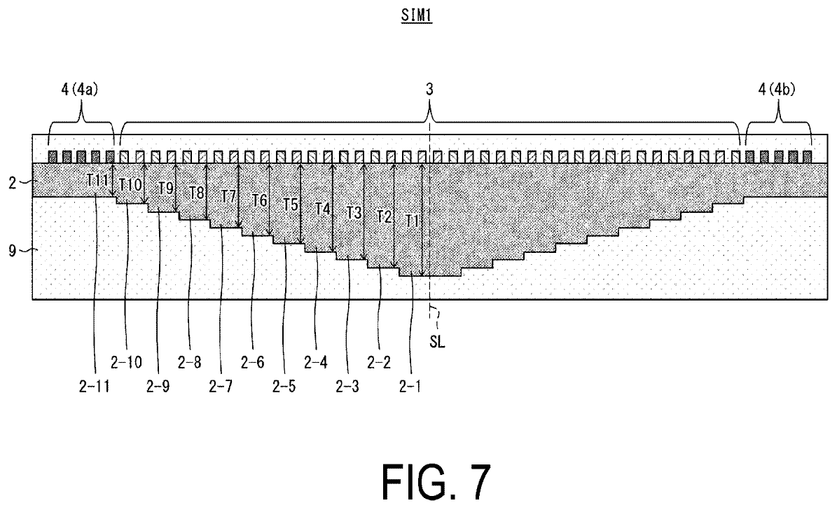

As illustrated in FIG. 7 below, the elastic wave device 100 may include a pair of reflectors 4a and 4b corresponding to the IDT electrodes 3. In the present specification, the reflectors 4a and 4b are also collectively referred to as reflectors 4. The reflectors 4 may be positioned to sandwich the IDT electrodes 3 in the x-direction.

Any one of at least one resonator 1 is referred to herein as a focus resonator 1A. In the example of FIG. 1, an IDT electrode 3 of a focus resonator 1A is illustrated. Any one of the at least one IDT electrode 3 is referred to as a focus IDT electrode, in the present specification. In the first embodiment, the IDT electrode 3 of the focus resonator 1A will be described as the focus IDT electrode. Thus, each description of the elastic wave device 100 according to the first embodiment may be read as a description of the focus resonator 1A unless otherwise inconsistent.

The support substrate 5 supports each part of the elastic wave device 100. Thus, the support substrate 5 may be located below the piezoelectric-body layer 2. As an example, the support substrate 5 may be a Si substrate.

Piezoelectric-body layer 2 may be composed of a single crystalline material having piezoelectricity. For example, the material of the piezoelectric-body layer 2 may be lithium tantalate (LiTaO₃, also referred to as LT) or lithium niobate (LiNbO₃, also referred to as LN). As an example, the piezoelectric-body layer 2 may be an LT layer.

The IDT electrode 3 may include, for example, an electrically conductive layer of metal. As an example, the metal may be Al. The IDT electrode 3 may further include a protective layer covering the electrically conductive layer. As an example, the material of the protective layer may be TEOS.

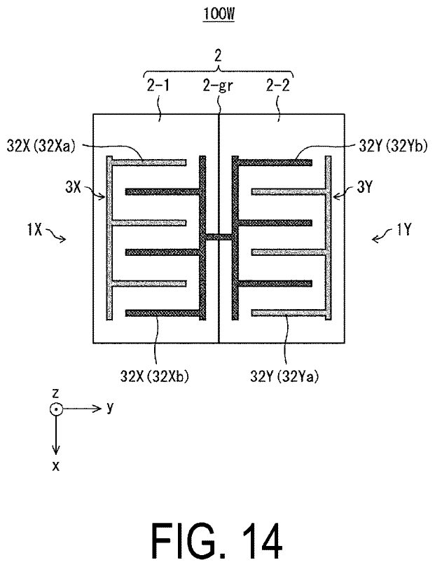

The IDT electrode 3 may include a first bus bar and a second bus bar (not illustrated in FIG. 1) facing each other in the y-direction. The IDT electrodes 3 may include (i) a plurality of first electrode fingers 32a connected to the first bus bar and (ii) a plurality of second electrode fingers 32b connected to the second bus bar. A first electrode finger 32a may extend from the first bus bar side to the second bus bar side in the y-direction. The second electrode finger 32b may extend from the second bus bar side to the first bus bar side in the y-direction. Thus, the second electrode fingers 32b and the first electrode fingers 32a may interpose respectively one another along the y-direction (see also, for example, FIG. 14 below.).

As illustrated in FIG. 1, the first electrode finger 32a and the second electrode finger 32b may be positioned alternately on the piezoelectric-body layer 2 and have generally constant spacing in the x-direction. In the present specification, the first electrode finger 32a and the second electrode finger 32b are also collectively referred to as the electrode finger 32. In the present specification, the electrode finger pitch of the IDT electrode 3 is denoted as p. p may be, for example, a pitch (repetition interval) in the x-direction between the centers of two adjacent electrode fingers 32. As an example, p may be set equal to a half value (λ/2) of a wavelength λ of the elastic wave excited by the IDT electrode 3. In this case, λ may be defined as the length twice p. Thus, in the first embodiment, a case where λ=2p is exemplified.

In the present specification, the length of the electrode finger 32 in the x-direction is referred to as a width w of the electrode finger 32. The w may be set appropriately according to the electric characteristics required for the elastic wave device 100, for example. As an example, the w may be set according to p. In the present specification, the ratio (w/p) of the width of the electrode finger to the electrode finger pitch is referred to as a Duty of the electrode finger. By changing the Duty, the frequency characteristics of the elastic wave device 100 can be controlled.

In the present specification, the maximum thickness of the piezoelectric-body layer 2 is expressed as Tmax. In the first embodiment, a case where Tmax is sufficiently small (in other words, when the piezoelectric-body layer 2 is thin enough) is exemplified. As an example, Tmax in the first embodiment may be not more than λ. In this case, the IDT electrode 3 may excite a plate wave (Lamb wave) as an elastic wave. As an example, the IDT electrode 3 may excite an A1 mode Lamb wave as a plate wave. Thus, in the first embodiment, a case where a plate wave (e.g., an A1 mode Lamb wave) propagates in the piezoelectric-body layer 2 is exemplified. However, the IDT electrode 3 may excite a bulk wave (thickness shear mode) as an elastic wave.

As illustrated in FIG. 1, the piezoelectric-body layer 2 may include (i) a first region 2-1 having a first thickness T1 and (i) a second region 2-2 having a second thickness T2 smaller than T1. The first embodiment illustrates a case where T1 is equal to Tmax. Thus, T2 in the first embodiment is smaller than Tmax. In the following description, the thickness of each region of the piezoelectric-body layer 2 is also collectively referred to as T.

As an example, both the first region 2-1 and the second region 2-2 may be located downward of the IDT electrode 3 (focus IDT electrode). Thus, within one resonator 1, both the first region 2-1 and the second region 2-2 may be located downward of one IDT electrode 3.

As illustrated in FIG. 1, the height position of the lower surface of the first region 2-1 may coincide with the height position of the lower surface of the second region 2-2. In other words, the first region 2-1 may project upward relative to the second region 2-2.

### Another Configuration Example of Elastic Wave Device 100

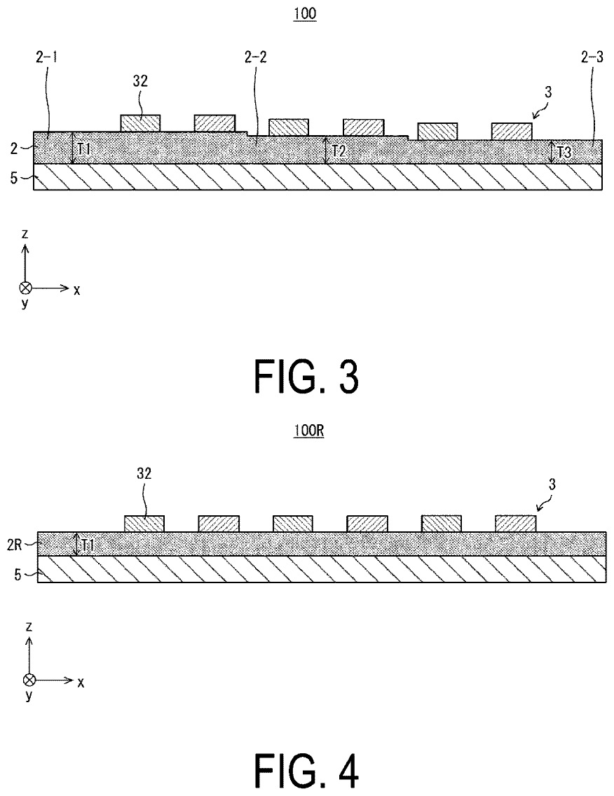

FIGS. 2 and 3 are diagrams each illustrating another configuration example of an elastic wave device 100. As illustrated in FIG. 2, the height position of the upper surface of the first region 2-1 may coincide with the height position of the upper surface of the second region 2-2. In other words, the first region 2-1 may project downward than the second region 2-2.

As illustrated in FIG. 3, the piezoelectric-body layer 2 may further include a third region 2-3 having a third thickness T3 smaller than the second thickness T2. As illustrated in FIG. 3, the height positions of the respective lower surfaces of the first region 2-1 to the third region 2-3 may coincide with each other. In other words, the second region 2-2 may project upward relative to the third region 2-3.

As described above, the elastic wave device according to one aspect of the present disclosure may include a piezoelectric-body layer (for convenience, referred to as the “stepped piezoelectric-body layer”) with stepped thickness. The piezoelectric-body layer 2 is an example of a stepped piezoelectric-body layer.

As described below, a main resonance frequency in the elastic wave device 100 may depend on T. Accordingly, for example, the main resonance frequency of a plate wave propagating in the first region 2-1 may differ from the main resonance frequency of a plate wave propagating in the second region 2-2.

### Elastic Wave Device 100R as Comparative Example

FIG. 4 illustrates a configuration example of an elastic wave device 100R as a comparative example. The elastic wave device 100R is an elastic wave device in which the piezoelectric-body layer 2 in the elastic wave device (e.g., the elastic wave device 100 in FIG. 1) according to one aspect of the present disclosure is substituted with a piezoelectric-body layer 2R illustrated in FIG. 4. For this reason, the elastic wave device 100R may be referred to as a substitute elastic wave device. The piezoelectric-body layer 2R may also be referred to as a substitute piezoelectric-body layer. As an example, the piezoelectric-body layer 2R may have either T1 or T2 as a single thickness T. In the example of FIG. 4, the piezoelectric-body layer 2R has T1 as a single thickness T.

As can be appreciated from each description below, the spurious signal in an elastic wave device (e.g., elastic wave device 100) according to one aspect of the present disclosure may be smaller than the spurious signal in a substitute elastic wave device. This is because an elastic wave device according to one aspect of the present disclosure, unlike the substitute elastic wave device, includes a stepped piezoelectric-body layer. As an example, an elastic wave device according to one aspect of the present disclosure may have a smaller number of the spurious signals than a substitute elastic wave device. As another example, an elastic wave device according to one aspect of the present disclosure may have a smaller spurious phase (e.g., maximum value of phase) than the substitute elastic wave device.

In addition, the spurious signal in an elastic wave device according to one aspect of the present disclosure may be the spurious signal caused by excitation other than excitation of a double wave, a triple wave, and main resonance. As described below, the stepped piezoelectric-body layer may reduce the spurious signals caused by excitation of a double wave, a triple wave, and a main resonance.

### First Preliminary Examination

The frequency characteristics of a typical elastic wave device (e.g., elastic wave device 100R) may also depend on T. Thus, for example, the desired frequency characteristics of an elastic wave device can be expected to be achieved by controlling T while maintaining the Duty constant.

In general, the main resonance frequency fr of an elastic wave device can depend on p and T. Thus, as a first preliminary examination, the inventor of the present invention (hereinafter simply abbreviated as “inventor”) performed simulations to find multiple pairs of p and T for which fr in the elastic wave device 100R is 4700 MHz.

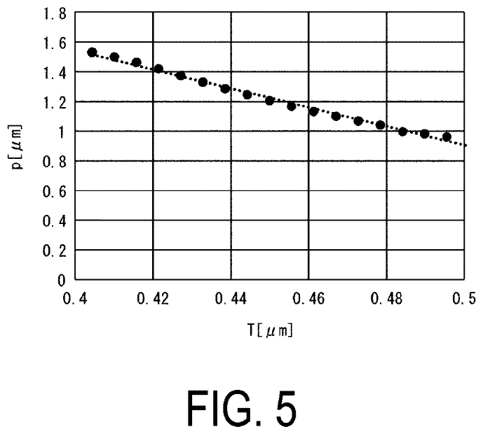

FIG. 5 is a graph illustrating an example of a correspondence between p and T obtained by the inventor. Specifically, FIG. 5 is a graph plotting a plurality of pairs of p and T for which fr in the elastic wave device 100R is 4700 MHZ. In the graph of FIG. 5, a horizontal axis represents T and a vertical axis represents p. As illustrated in FIG. 5, there is a certain degree of correlation between T and p. FIG. 5 also illustrates regression line fitted using multiple pairs of plotted values. The regression line in the example of FIG. 5 is T=−6.365p+4.088 - - - (1).

### Second Preliminary Examination

The phase of the impedance of an elastic wave device (hereinafter simply abbreviated as “phase”) may also depend on p and T. In particular, when T is small, the resonance characteristics of an elastic wave device may depend greatly on T because the plate wave propagates in the piezoelectric-body layer.

Thus, as a second preliminary investigation, the inventor determined p corresponding to a predetermined single T in the elastic wave device 100R using the above equation (1). Then, the inventor derived phases corresponding to various T by performing a simulation using T and p set as described above for the elastic wave device 100R.

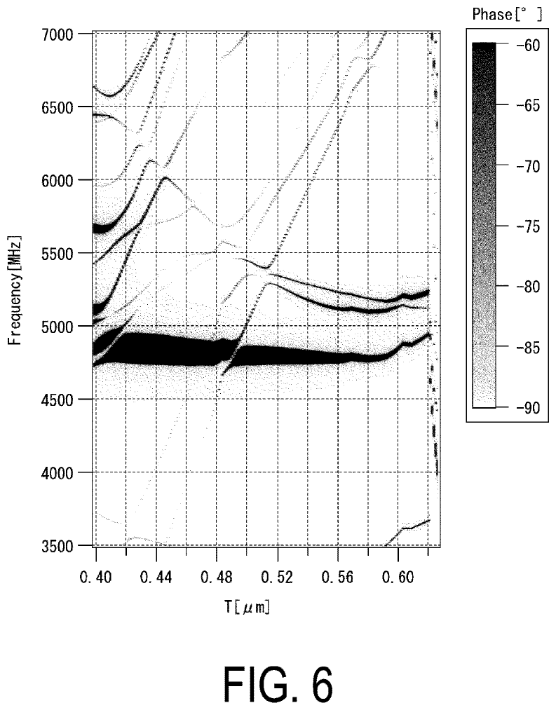

FIG. 6 is a contour map illustrating an example of a correspondence between T, frequency, and phase obtained by the inventor. In FIG. 6, a horizontal axis (first axis) represents T, and a vertical axis (second axis) represents frequency. In FIG. 6, a height axis (third axis) represents phase (degree).

In the example of FIG. 6, a phase of −90° means that there is no resonance or spurious signals in the phase characteristics of the elastic wave device 100R. In contrast, a phase sufficiently large compared to −90° means that there is a resonance peak or a spurious signal in the phase characteristics. As an example, when T=0.44 μm, it can be seen from FIG. 6 that (i) there is a resonance peak in the frequency band of approximately 4700 to 5000 MHz, and (ii) there is a large spurious peak in the frequency band of approximately 6000 MHz.

### Examination Using Simulation Model Including Stepped Piezoelectric-body Layer

Based on the first and second preliminary examinations, the inventor has constructed the simulation model SIM1 of an elastic wave device that includes a stepped piezoelectric-body layer. FIG. 7 illustrates an overview of SIM1. As illustrated in FIG. 7, SIM1 is symmetrical about a symmetry line SL in the x-direction. The piezoelectric-body layer 2 in SIM1 includes a first region 2-1 to an eleventh region 2-11. That is, the piezoelectric-body layer 2 in SIMI has the first thickness T1 to an eleventh thickness T11.

The inventor set the material of the piezoelectric-body layer 2 in SIMI to LT. The inventor set
T1=0.50 μm,
T2=0.49 μm,
T3=0.48 μm,
T4=0.47 μm,
T5=0.46 μm,
T6=0.45 μm,
T7=0.44 μm,
T8=0.43 μm,
T9=0.42 μm,
T10=0.41 μm, and
T11=0.40 μm.

In the example of FIG. 7, air layers 9 are each located above and below the piezoelectric-body layer 2. Hereinafter, the air layer 9 located below the piezoelectric-body layer 2 is referred to as a lower air layer. In SIM1, the support substrate 5 located below the lower air layer is omitted. However, of course, in the actual elastic wave device, the support substrate 5 may be located below the lower air layer. Thus, for example, an elastic wave device according to one aspect of the present disclosure may include a membrane structure having a hollow portion surrounded by the support substrate 5 and the piezoelectric-body layer 2.

In the example of FIG. 7, a pair of reflectors 4a and 4b are positioned so as to sandwich the IDT electrodes 3 in the x-direction. In SIM1, the inventor set the number of electrode fingers of each of the reflectors 4a and 4b to 20.

In addition, in SIM1, the inventor set, for the IDT electrode 3, the conductive layer as A1 with thickness of 0.13 μm, the protective layer as TEOS with thickness of 0.013 μm, the Duty as 0.55, and the number of electrode fingers as 110.

Subsequently, the inventor set a plurality of p corresponding to T1 to T11 so that fr in SIM1 is 4700 MHz while maintaining Duty=0.55. Hereinafter, for example, p corresponding to T1 is referred to as p1. The p1 represents p in the electrode finger 32 located above the first region 2-1.

First, the inventor set p7=1.275 μm for T7=0.44 μm. Then, the inventor interpolated p1 to p6 and p8 to p11 from T1 to T11 and p7 based on the equation (1) above. As described above, the inventor set p1 to p11 according to T1 to T11, respectively.

In addition, the inventor constructed a simulation model (comparative model) according to the comparative example to compare with SIM1. The comparative model corresponds to the above-mentioned elastic wave device 100R. The inventors set the single thickness (Tmax) of the piezoelectric-body layer 2R in the comparative model to T7 (0.44 μm). The inventor then sets p in the comparative model to a single value p7 (1.275 μm). Other conditions in the comparative model are equivalent to SIM1.

The comparative model satisfies λ=2×p=2.55 μm. Thus, the comparative model satisfies Tmax<λ. As is clear from the above numerical values in SIM1, Tmax<λ is satisfied in SIM1 as well. When the IDT electrode 3 has a plurality of p, λ may be defined based on any one of the plurality of p. As an example, in SIM1, λ may be specified as λ=2×p1. As another example, in SIM1, λ may be specified as λ=2×p11.

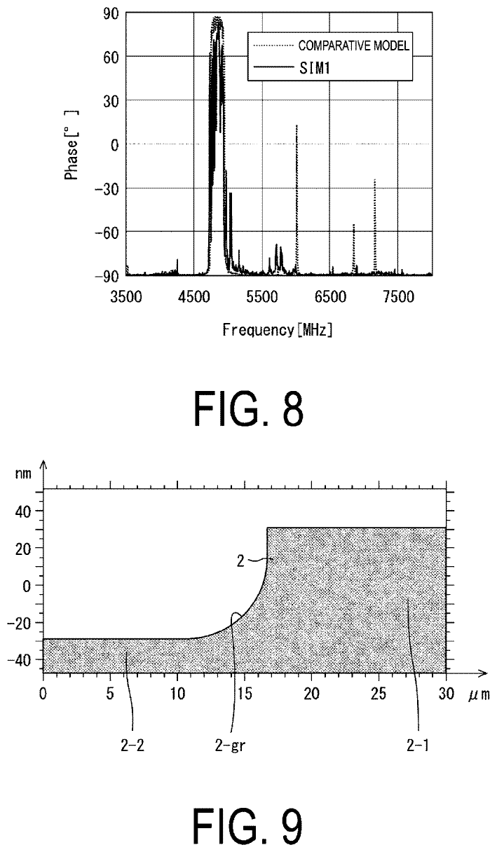

Subsequently, the inventor performed simulations for each of SIM1 and the comparison model to derive the phase characteristics of SIM1 and the comparative model. FIG. 8 is a graph illustrating an example of the phase characteristics for each of SIMI and the comparative model, derived by simulation. In the graph of FIG. 8, a horizontal axis represents the frequency and a vertical axis represents the phase.

As illustrated in FIG. 8, in the comparative model, there are a plurality of spurious signals larger than fr on the high-frequency side. In contrast, in SIM1, the spurious signals are reduced. Specifically, in SIM1, (i) the number of spurious signals is reduced and (ii) the maximum phase value of the spurious signals is reduced compared with the comparative model.

In addition, in SIM1, the spurious signals caused by excitation of the main resonance are reduced. In SIM, spurious signals caused by excitation of the double wave and triple wave are also reduced.

As described above, the inventor has newly found through simulations for the elastic wave device 100 that both the main resonance frequency and the spurious frequency in the elastic wave device 100 can be controlled by controlling the thickness of the piezoelectric-body layer 2. The elastic wave device 100, for example, enables the main resonance frequency and the spurious frequency to be controlled while maintaining the pitch and Duty of the IDT electrode 3 by using a stepped piezoelectric-body layer.

In the related art, an attempt has been made to set the desired main resonance frequency by controlling the pitch and Duty of the IDT electrode 3. However, in this case, the spurious frequency may also vary with the change of the pitch and Duty of the IDT electrode 3. Thus, in the related art, properly controlling both the main resonance frequency and the spurious frequency is difficult.

By contrast, the elastic wave device 100 can maintain the pitch and Duty of the IDT electrode 3, so that both the main resonance frequency and the spurious frequency can be appropriately controlled. However, as is clear from the above description of SIM1, the pitch of the IDT electrode 3 may be controlled in the elastic wave device 100 together with the thickness control of the piezoelectric-body layer 2. Alternatively, the Duty control of the IDT electrode 3 may be performed in the elastic wave device 100 together with the thickness control of the piezoelectric-body layer 2.

### Examination of Inclined Region

The inventor actually fabricated the piezoelectric-body layer 2, which is analyzed with AFM (Atomic Force Microscope). FIG. 9 schematically illustrates an AFM image of the fabricated piezoelectric-body layer 2. As illustrated in FIG. 9, it has been found that the fabricated piezoelectric-body layer 2 includes an inclined region, which is located between the first region 2-1 and the second region 2-2 and can have a inclined region 2-gr with the thickness increasing from the second region 2-2 side to the first region 2-1 side.

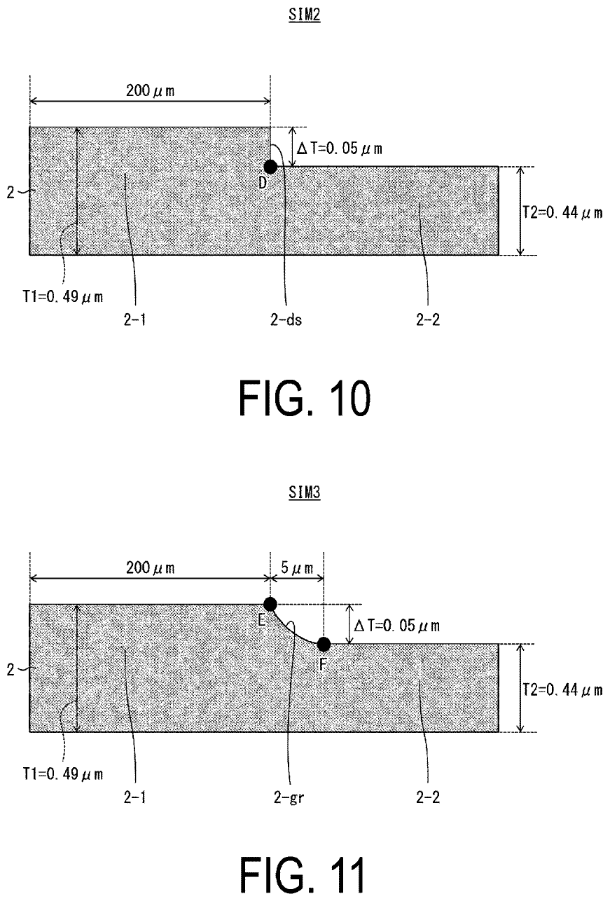

The inventor built two simulation models for piezoelectric-body layer 2 to examine the benefits of the inclined region 2-gr. SIM2 in FIG. 10 is a first simulation model for piezoelectric-body layer 2. The piezoelectric-body layer 2 in SIM2 includes a stepped portion 2-ds, which (i) connects a first region 2-1 and a second region 2-2, and (ii) is orthogonal to the first region 2-1 and the second region 2-2. In the example of FIG. 10, T is equal to 0.49 μm and T2 is equal to 0.44 μm. Thus, the height of the stepped portion 2-ds is ΔT=T1−T2=0.05 μm.

As illustrated in FIG. 10, the piezoelectric-body layer 2 in SIM2 does not include the inclined region 2-gr. Thus, when moving along the x-direction from one of the first region 2-1 and the second region 2-2 to the other, T changes discontinuously (rapidly) with the stepped portion 2-ds as the boundary.

The inventor performed a simulation on SIM2 and derived the stress (more specifically, the maximum principal stress) at a point D (lower position of the stepped portion 2-ds) in FIG. 10. As a result, the stress at the point D was 18 MPa.

SIM3 in FIG. 11 is the second simulation model for piezoelectric-body layer 2. The piezoelectric-body layer 2 in SIM3 includes an inclined region 2-gr instead of the stepped portion 2-ds in SIM2. As illustrated in FIG. 11, the height of the inclined region 2-gr is ΔT=T1−T2=0.05 μm. The length of the inclined region 2-gr in the x-direction is 5 μm.

The inclined region 2-gr in SIM3 smoothly connects the first region 2-1 and the second region 2-2 in the z-direction (thickness direction, height direction). Thus, when moving along the x-direction from one of the first region 2-1 and the second region 2-2 to the other, T changes continuously (slowly) in the inclined region 2-gr.

The inventor performed simulations on SIM3 to derive the stresses at a point E (at the top of the inclined region 2-gr) and a point F (at the bottom of the inclined region 2-gr) in FIG. 11. As a result, the stress at the point E was 7.5 MPa, and the stress at the point F was 8 MPa. Thus, the inventor newly found through the simulation for the piezoelectric-body layer 2 that the stress can be reduced to about 40% by providing the inclined region 2-gr in the piezoelectric-body layer 2 compared with the case without the inclined region 2-gr.

When the piezoelectric-body layer 2 is sufficiently thin, the stress concentration due to the vibration of the piezoelectric-body layer 2 (thin film vibration) is likely to occur at and near the boundary between the first region 2-1 and the second region 2-2. For example, the simulation results in SIM2 illustrate that particularly large stress can occur in the stepped portion 2-ds of the piezoelectric-body layer 2.

Thus, as illustrated in FIG. 11, the piezoelectric-body layer 2 according to one aspect of the present disclosure may include the inclined region 2-gr. In this case, the stress generated at and near the above-mentioned boundary can be mitigated. Thus, the risk of the piezoelectric-body layer 2 being damaged due to the stress can be reduced.

### Configuration Example of Elastic Wave Device 100V

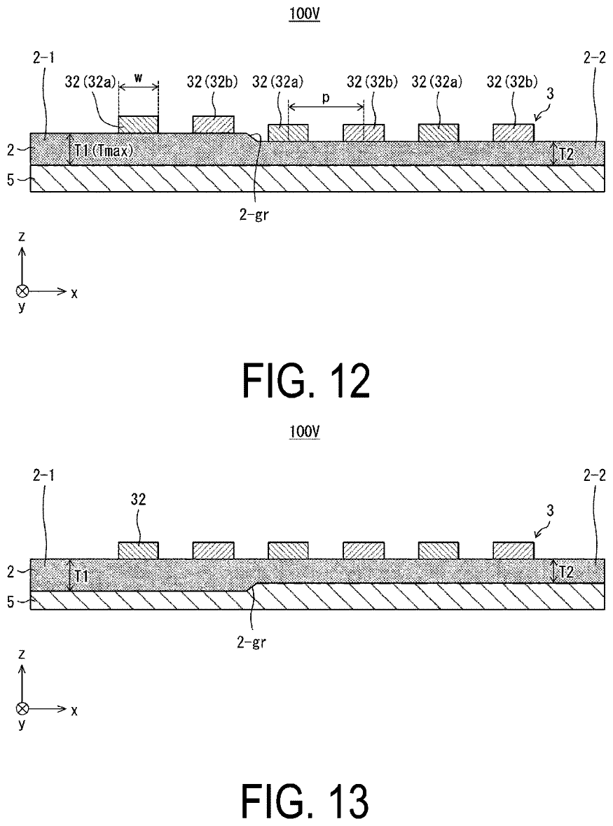

FIG. 12 illustrates a configuration example of an elastic wave device 100V. The elastic wave device 100V is an example of an elastic wave device created based on the above knowledge about the inclined region. The elastic wave device 100V is another example of an elastic wave device 100.

As illustrated in FIG. 12, the piezoelectric-body layer 2 of the elastic wave device 100V may include the inclined region 2-gr, which is located between the first region 2-1 and the second region 2-2 and has a thickness that increases from the second region 2-2 side to the first region 2-1 side.

As an example, the inclined region 2-gr of the elastic wave device 100V may have a slope above the piezoelectric-body layer 2 (i.e., the IDT electrode 3 side). As illustrated in FIG. 12, the slope may be a downward slope that descends from the first region 2-1 to the second region 2-2.

As is apparent from the above descriptions, the elastic wave device 100V includes a stepped piezoelectric-body layer (piezoelectric-body layer 2 with the first region 2-1 and the second region 2-2) to reduce spurious signals. In addition, the piezoelectric-body layer 2 has the inclined region 2-gr to further mitigate stress in the piezoelectric-body layer 2. Thus, the elastic wave device 100V enables to reduce stress in the piezoelectric-body layer 2, in addition to mitigate spurious signals.

### Another Configuration Example of Elastic Wave Device 100V

FIG. 13 illustrates another configuration example of the elastic wave device 100V. As illustrated in FIG. 13, the inclined region 2-gr in the elastic wave device 100V may have a slope below the piezoelectric-body layer 2 (i.e., on the support substrate 5 side). As illustrated in FIG. 13, the slope may be an upward slope that rises from the first region 2-1 to the second region 2-2.

### Supplementary Description of Elastic Wave Device 100V

The elastic wave device 100V may further include a multilayer reflective film in which (i) a low acoustic impedance layer having an acoustic impedance lower than piezoelectric-body layer 2 and (ii) a high acoustic impedance layer having an acoustic impedance higher than piezoelectric-body layer 2 are alternately laminated.

As an example, the multilayer reflective film may be located between the piezoelectric-body layer 2 and the support substrate 5. The multilayer reflective film may include one or more laminated units each composed of one low acoustic impedance layer and one high acoustic impedance layer laminated together. As an example, the multilayer reflective film may include four laminated units. Material for low acoustic impedance layer includes SiO₂ or the like. Material for high acoustic impedance layer includes HfO₂ or the like.

### Second Embodiment

FIG. 14 is a diagram illustrating a configuration example of an elastic wave device 100W of a second embodiment. The elastic wave device 100W may include a first resonator 1X and a second resonator 1Y as a resonator 1. The elastic wave device 100W may include, as the IDT electrode 3, (i) a first IDT electrode 3X located on the first region 2-1 and (ii) a second IDT electrode 3Y located on the second region 2-2.

The first resonator 1X may be located on the first region 2-1. Thus, for example, the first IDT electrode 3X may be the IDT electrode 3 of the first resonator 1X. The first IDT electrode 3X may include a plurality of first electrode fingers 32Xa and a plurality of second electrode fingers 32Xb. In the present specification, the first electrode finger 32Xa and the second electrode finger 32Xb are also collectively referred to as an electrode finger 32X.

The second resonator 1Y may be located on the second region 2-2. Thus, for example, the second IDT electrode 3Y may be the IDT electrode 3 of the second resonator 1Y. The second IDT electrode 3Y may include a plurality of first electrode fingers 32Ya and a plurality of second electrode fingers 32Yb. The first electrode finger 32Ya and the second electrode finger 32Yb are also collectively referred to herein as an electrode finger 32Y.

Thus, in the elastic wave device 100W, (i) the first region 2-1 may be located below one resonator (e.g., first resonator 1X with the first IDT electrode 3X) and (ii) the second region 2-2 may be located below another resonator (e.g., second resonator 1Y with the second IDT electrode 3Y). In the present case, as illustrated in FIG. 14, the inclined region 2-gr may be located between the first IDT electrode 3X and the second IDT electrode 3Y in the y-direction. In other words, the inclined region 2-gr may be located between the first resonator 1X and the second resonator 1Y in the y-direction.

As an example, the elastic wave device 100W may be a ladder filter that includes a plurality of resonators 1. In this case, the elastic wave device 100W may include at least one serial resonator and at least one parallel resonator as a plurality of resonators 1. As an example, one of the first resonator 1X and the second resonator 1Y may be a serial resonator and the other may be a parallel resonator. As another example, both the first resonator 1X and the second resonator 1Y may be serial resonators. As yet another example, both the first resonator 1X and the second resonator 1Y may be parallel resonators.

### Supplementary Description of First and Second Embodiments

As is apparent from the description in the first embodiment and the second embodiment, the piezoelectric-body layer in the elastic wave device according to one aspect of the present disclosure may include N different regions from the first region to the N-th region. Nis a natural number not less than 2. The region i may have an i-th thickness. Hereinafter, the i-th thickness is also referred to as T (i). i is a natural number not less than 1 and not more than N. As an example, T1 and T2 in FIG. 1 correspond to T(1) and T(2), respectively.

In the piezoelectric-body layer, T(i)>T(i+1) for any i may be satisfied. Thus, for example, T(1)=Tmax>T(2)> - - - >T(N−1)>T(N) may be satisfied. In this case, the substitute piezoelectric-body layer described above may have any one of N different thicknesses from the first thickness to N-th thickness as a single thickness.

In addition, the piezoelectric-body layer may include an inclined region, which is located between the i-th region and the (i+1)-th region and has a thickness that increases from the (i+1)-th region to the i-th region. Thus, the piezoelectric-body layer may have up to (N−1) different inclined regions.

### Third Embodiment

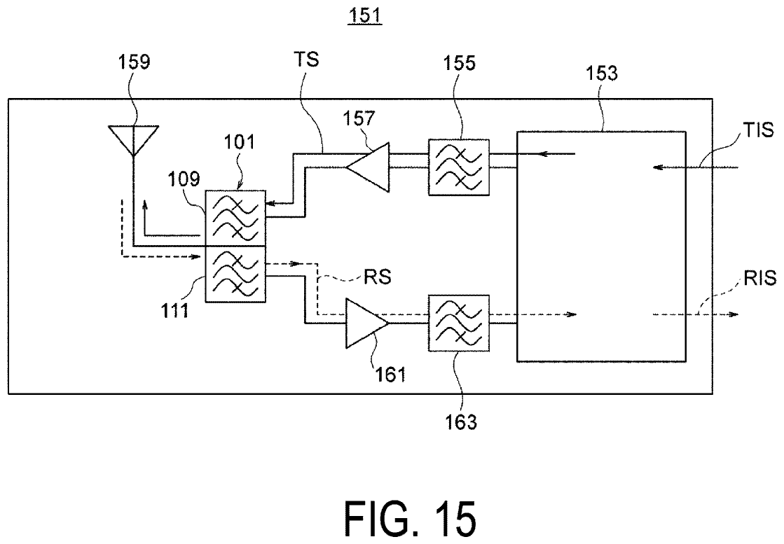

FIG. 15 is a diagram illustrating a schematic configuration of a communication apparatus 151 in the third embodiment. The communication apparatus 151 is an application of an elastic wave device according to an aspect of the present disclosure, and performs radio communication using radio waves. The communication apparatus 151 may include one duplexer 101 as a transmission filter 109 and another duplexer 101 as a reception filter 111. Each of the two duplexers 101 may include an elastic wave device (e.g., elastic wave device 100, 100V, or 100W) according to one aspect of the present disclosure. As such, the communication apparatus 151 may include an elastic wave device according to one aspect of the present disclosure.

In the communication apparatus 151, a transmission information signal TIS containing the information to be transmitted may be modulated and frequency-raised (converted to a high frequency signal having a carrier frequency) by a radio frequency-integrated circuit (RF-IC) 153, and converted into a transmission signal TS. A bandpass filter 155 may remove unnecessary components of the TS other than the passband for transmission. The TS after removal of unnecessary components may then be amplified by an amplifier 157 and input to the transmission filter 109.

The transmission filter 109 may remove unnecessary components other than the passband for transmission from an input transmission signal TS. The transmission filter 109 may output the TS after removing the unnecessary components to an antenna 159 via the antenna terminal (e.g., TCin described above). The antenna 159 may convert the TS, which is an electrical signal input to itself, into a radio wave as a radio signal and transmit the radio wave to the outside of the communication apparatus 151.

The antenna 159 may convert the received radio wave from the outside into a reception signal RS, which is an electrical signal, and input the RS to the reception filter 111 via the antenna terminal. The reception filter 111 may remove unnecessary components other than the passband for reception from the input RS. The reception filter 111 may output the reception signal RS after removing unnecessary components to an amplifier 161. The output RS may be amplified by the amplifier 161. A bandpass filter 163 may remove unnecessary components other than the passband for reception from the amplified RS. The frequency of the removed RS may be reduced and demodulated by the RF-IC 153 and converted into a received information signal RIS.

The TIS and RIS may be low-frequency signals (baseband signals) containing appropriate information. For example, the TIS and RIS may be analog audio signals or digitized audio signals. The radio signal passband may be set appropriately and may conform to various known standards.

### Conclusion

An elastic wave device according to a first aspect of the present disclosure may include a support substrate, a piezoelectric-body layer located on the support substrate, and at least one IDT electrode located on the piezoelectric-body layer.

When a wavelength λ of an elastic wave excited by the IDT electrode is defined as a length twice an electrode finger pitch of the IDT electrode, a maximum thickness of the piezoelectric-body layer is not more than λ. The IDT electrode excites a plate wave or a bulk wave as the elastic wave.

The piezoelectric-body layer may include:
a first region having a first thickness;
a second region having a second thickness smaller than the first thickness; and
an inclined region located between the first region and the second region, and having a thickness that increases from a side at which the second region is provided to a side at which the first region is provided.

In an elastic wave device according to a second aspect of the present disclosure, in the first aspect,
the IDT electrode may excite a plate wave as the elastic wave, and the plate wave may be an A1 mode Lamb wave.

In an elastic wave device according to a third aspect of the present disclosure, in the first aspect, the IDT electrode may excite a bulk wave as the elastic wave.

In an elastic wave device according to a fourth aspect of the present disclosure, in the first or second aspect, a main resonance frequency of the plate wave propagating in the first region may be different from a main resonance frequency of the plate wave propagating in the second region.

In an elastic wave device according to a fifth aspect of the present disclosure, in any one of the first to fourth aspects, an elastic wave device in which the piezoelectric-body layer in the elastic wave device is substituted with a substitute piezoelectric-body layer is referred to as a substitute elastic wave device, the substitute piezoelectric-body layer has either the first thickness or the second thickness as a single thickness, and a spurious signal in the elastic wave device may be smaller than a spurious signal in the substitute elastic wave device.

In an elastic wave device according to a sixth aspect of the present disclosure, in the fifth aspect, the spurious signal in the elastic wave device may be a spurious signal caused by excitation other than excitation of a double wave, a triple wave, and main resonance.

An elastic wave device according to a seventh aspect of the present disclosure, in any one of the first to sixth aspects, may include as the at least one IDT electrode a first IDT electrode located on the first region, and a second IDT electrode located on the second region.

In an elastic wave device according to an eighth aspect of the present disclosure, in any one of the first to sixth aspects, any one of the at least one IDT electrode is referred to as a focus IDT electrode, and both the first region and the second region may be located downward of the focus IDT electrode.

In an elastic wave device according to a ninth aspect of the present disclosure, in any one of the first to eighth aspects, the inclined region may have a slope on a side at which the IDT electrode of the piezoelectric-body layer is provided.

In an elastic wave device according to a tenth aspect of the present disclosure, in any one of the first to eighth aspects, the inclined region may have a slope on a side at which the support substrate of the piezoelectric-body layer is provided.

In an elastic wave device according to an eleventh aspect of the present disclosure, in any one of the first to tenth aspects, the piezoelectric-body layer may further include a third region having a third thickness smaller than the second thickness.

An elastic wave device according to a twelfth aspect of the present disclosure, in any one of the first to eleventh aspects, may further include a membrane structure having a hollow portion surrounded by the support substrate and the piezoelectric-body layer.

An elastic wave device according to a thirteenth aspect of the present disclosure, in any one of the first to twelfth aspects, may further include a multilayer reflective film being laminated alternately with (i) a low acoustic impedance layer having a lower acoustic impedance than the piezoelectric-body layer, and (ii) a high acoustic impedance layer having a higher acoustic impedance than the piezoelectric-body layer.

An elastic wave device according to a fourteenth aspect of the present disclosure, may include the elastic wave device according to any one of the first to thirteenth aspects.

### Supplementary Note

The invention according to the present disclosure has been described above on the basis of various drawings and embodiments. However, the invention according to the present disclosure is not limited to the above-mentioned embodiments. That is, the embodiments of the invention according to the present disclosure can be modified in various ways within the scope illustrated in the present disclosure, and embodiments obtained by appropriately combining the technical means disclosed in different embodiments are also included in the technical scope of the invention according to the present disclosure. In other words, it should be noted that it is easy for a person skilled in the art to make various modifications or modifications based on the present disclosure. Note that these variations or modifications are included within the scope of the present disclosure.

### REFERENCE SIGNS

1 Resonator
1A Focus resonator (resonator)
1X First resonator (resonator)
1Y Second resonator (resonator)
2 Piezoelectric-body layer
2-1 First region
2-2 Second region
2-gr Inclined region
2-3 Third region
2R Piezoelectric-body layer (alternate piezoelectric-body layer)
3 IDT electrode (focus IDT electrode)
3X First IDT electrode
3Y Second IDT electrode
5 Support substrate
100 Elastic wave device
100V, 100W Elastic wave device (elastic wave device with inclined region)
100R Elastic wave device (substitute elastic wave device)
151 Communication apparatus

1. An elastic wave device, comprising:
a support substrate;
a piezoelectric-body layer located on the support substrate; and
at least one IDT electrode located on the piezoelectric-body layer,
wherein, when a wavelength λ of an elastic wave excited by the IDT electrode is defined as a length twice an electrode finger pitch of the IDT electrode, a maximum thickness of the piezoelectric-body layer is not more than λ,
the IDT electrode excites a plate wave or a bulk wave as the elastic wave, and
the piezoelectric-body layer comprises:
a first region having a first thickness;
a second region having a second thickness smaller than the first thickness; and
an inclined region located between the first region and the second region, and having a thickness that increases from a side at which the second region is provided to a side at which the first region is provided.

2. The elastic wave device according to claim 1, wherein
the IDT electrode excites a plate wave as the elastic wave, and
the plate wave is an A1 mode Lamb wave.

3. The elastic wave device according to claim 1, wherein the IDT electrode excites a bulk wave as the elastic wave.

4. The elastic wave device according to claim 1, wherein a main resonance frequency of the plate wave propagating in the first region is different from a main resonance frequency of the plate wave propagating in the second region.

5. The elastic wave device according to claim 1, wherein
an elastic wave device in which the piezoelectric-body layer in the elastic wave device is substituted with a substitute piezoelectric-body layer is referred to as a substitute elastic wave device,
the substitute piezoelectric-body layer has the first thickness or the second thickness as a single thickness, and
a spurious signal in the elastic wave device is smaller than a spurious signal in the substitute elastic wave device.

6. The elastic wave device according to claim 5, wherein the spurious signal in the elastic wave device is a spurious signal caused by excitation other than excitation of a double wave, a triple wave, and main resonance.

7. The elastic wave device according to claim 1, further comprising as the at least one IDT electrode:
a first IDT electrode located on the first region; and
a second IDT electrode located on the second region.

8. The elastic wave device according to claim 1, wherein
any one of the at least one IDT electrode is referred to as a focus IDT electrode, and
both the first region and the second region are located downward of the focus IDT electrode.

9. The elastic wave device according to claim 1, wherein
the inclined region has a slope on a side at which the IDT electrode of the piezoelectric-body layer is provided.

10. The elastic wave device according to claim 1, wherein
the inclined region has a slope on a side at which the support substrate of the piezoelectric-body layer is provided.

11. The elastic wave device according to claim 1, wherein
the piezoelectric-body layer further comprises a third region having a third thickness smaller than the second thickness.

12. The elastic wave device according to claim 1, further comprising a membrane structure having a hollow portion surrounded by the support substrate and the piezoelectric-body layer.

13. The elastic wave device according to claim 1, further comprising a multilayer reflective film being laminated alternately with:
(i) a low acoustic impedance layer having a lower acoustic impedance than the piezoelectric-body layer; and
(ii) a high acoustic impedance layer having a higher acoustic impedance than the piezoelectric-body layer.

14. A communication apparatus, comprising the elastic wave device according to claim 1.
